(19) United States
(12) Patent Application Publication
(10) Pub. No.: US 2010/0051090 A1
(43) Pub. Date: Mar. 4, 2010

(54) FOUR TERMINAL MULTI-JUNCTION THIN FILM PHOTOVOLTAIC DEVICE AND METHOD

(75) Inventor: HOWARD W.H. LEE, Saratoga, CA (US)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: STION CORPORATION, San Jose, CA (US)

(21) Appl. No.: 12/512,979

(22) Filed: Jul. 30, 2009

Related U.S. Application Data
(60) Provisional application No. 61/092,732, filed on Aug. 28, 2008.

(51) Int. Cl. H01L 31/052

(52) U.S. Cl. 136/246

(57) ABSTRACT

A multi-junction photovoltaic cell device. The device includes a lower cell and an upper cell, which is operably coupled to the lower cell. In a specific embodiment, the lower cell includes a lower glass substrate material, e.g., transparent glass. The lower cell also includes a lower electrode layer made of a reflective material overlying the glass material. The lower cell includes a lower absorber layer overlying the lower electrode layer. In a specific embodiment, the absorber layer is made of a semiconductor material having a band gap energy in a range of Eg=0.7 to 1 eV, but can be others. In a specific embodiment, the lower cell includes a lower window layer overlying the lower absorber layer and a lower transparent conductive oxide layer overlying the lower window layer. The upper cell includes a p+ type transparent conductor layer overlying the lower transparent conductive oxide layer. In a preferred embodiment, the p+ type transparent conductor layer is characterized by traversing electromagnetic radiation in at least a wavelength range from about 700 to about 630 nanometers and filtering electromagnetic radiation in a wavelength range from about 490 to about 450 nanometers. In a specific embodiment, the upper cell has an upper p type absorber layer overlying the p+ type transparent conductor layer. In a preferred embodiment, the p type conductor layer made of a semiconductor material has a band gap energy in a range of Eg=1.6 to 1.9 eV, but can be others. The upper cell also has an upper n type window layer overlying the upper p type absorber layer, an upper transparent conductive oxide layer overlying the upper n type window layer, and an upper glass material overlying the upper transparent conductive oxide layer.

### CROSS-REFERENCES TO RELATED APPLICATIONS

This application claims priority to U.S. Provisional Patent Application No. 61/092,732, filed Aug. 28, 2008, entitled “FOUR TERMINAL MULTI-JUNCTION THIN FILM PHOTOVOLTAIC DEVICE AND METHOD” by inventor HOWARD W. H. LEE commonly assigned and incorporated by reference herein for all purposes.

### STATEMENT AS TO RIGHTS TO INVENTIONS MADE UNDER FEDERALLY SPONSORED RESEARCH AND DEVELOPMENT

NOT APPLICABLE

### REFERENCE TO A “SEQUENCE LISTING,” A TABLE, OR A COMPUTER PROGRAM LISTING APPENDIX SUBMITTED ON A COMPACT DISK

NOT APPLICABLE

### BACKGROUND OF THE INVENTION

The present invention relates generally to photovoltaic materials and manufacturing method. More particularly, the present invention provides a method and structure for manufacture of high efficiency multi-junction thin film photovoltaic cells. Merely by way of example, the present method and materials include absorber materials made of copper indium disulfide species, copper tin sulfide, iron disulfide, or others for multi-junction cells.

From the beginning of time, mankind has been challenged to find way of harnessing energy. Energy comes in the forms such as petrochemical, hydroelectric, nuclear, wind, biomass, solar, and more primitive forms such as wood and coal. Over the past century, modern civilization has relied upon petrochemical energy as an important energy source. Petrochemical energy includes gas and oil. Gas includes lighter forms such as butane and propane, commonly used to heat homes and serve as fuel for cooking. Gas also includes gasoline, diesel, and jet fuel, commonly used for transportation purposes. Heavier forms of petrochemicals can also be used to heat homes in some places. Unfortunately, the supply of petrochemical fuel is limited and essentially fixed based upon the amount available on the planet Earth. Additionally, as more people use petroleum products in growing amounts, it is rapidly becoming a scarce resource, which will eventually become depleted over time.

More recently, environmentally clean and renewable sources of energy have been desired. An example of a clean source of energy is hydroelectric power. Hydroelectric power is derived from electric generators driven by the flow of water produced by dams such as the Hoover Dam in Nevada. The electric power generated is used to power a large portion of the city of Los Angeles in California. Clean and renewable sources of energy also include wind, waves, biomass, and the like. That is, windmills convert wind energy into more useful forms of energy such as electricity. Still other types of clean energy include solar energy. Specific details of solar energy can be found throughout the present background and more particularly below.

Solar energy technology generally converts electromagnetic radiation from the sun to other useful forms of energy. These other forms of energy include thermal energy and electrical power. For electrical power applications, solar cells are often used. Although solar energy is environmentally clean and has been successful to a point, many limitations remain to be resolved before it becomes widely used throughout the world. As an example, one type of solar cell uses crystalline materials, which are derived from semiconductor material ingots. These crystalline materials can be used to fabricate optoelectronic devices that include photovoltaic and photodiode devices that convert electromagnetic radiation into electrical power. However, crystalline materials are often costly and difficult to make on a large scale. Additionally, devices made from such crystalline materials often have low energy conversion efficiencies. Other types of solar cells use “thin film” technology to form a thin film of photosensitive material to be used to convert electromagnetic radiation into electrical power. Similar limitations exist with the use of thin film technology in making solar cells. That is, efficiencies are often poor. Additionally, film reliability is often poor and cannot be used for extensive periods of time in conventional environmental applications. Often, thin films are difficult to mechanically integrate with each other. These and other limitations of these conventional technologies can be found throughout the present specification and more particularly below.

From the above, it is seen that improved techniques for manufacturing photovoltaic materials and resulting devices are desired.

### BRIEF SUMMARY OF THE INVENTION

According to embodiments of the present invention, a method and a structure for forming thin film semiconductor materials for photovoltaic applications are provided. More particularly, the present invention provides a method and structure for manufacture of high efficiency multi-junction thin film photovoltaic cells. Merely by way of example, the present method and materials include absorber materials made of copper indium disulfide species, copper tin sulfide, iron disulfide, or others for multi-junction cells.

In a specific embodiment, the present invention provides a multi-junction photovoltaic cell device. The device includes a lower cell and an upper cell, which is operably coupled to the lower cell. In a specific embodiment, the lower cell includes a lower glass substrate material, e.g., transparent glass. The lower cell also includes a lower electrode layer made of a reflective material overlying the glass material. The lower cell includes a lower absorber layer overlying the lower electrode layer. In a specific embodiment, the absorber layer is made of a semiconductor material having a band gap energy in a range of Eg=0.7 to 1 eV, but can be others. In a specific embodiment, the lower cell includes a lower window layer overlying the lower absorber layer and a lower transparent conductive oxide layer overlying the lower window layer. The upper cell includes a p+ type transparent conductor layer overlying the lower transparent conductive oxide layer. In a preferred embodiment, the p+ type transparent conductor layer is characterized by traversing electromagnetic radiation in at least a wavelength range from about 700 to about 630 nanometers and filtering electromagnetic radiation in a wavelength range from about 490 to about 450 nanometers. In a specific embodiment, the upper cell has an upper p type absorber layer overlying the p+ type transparent conductor layer. In a preferred embodiment, the p type conductor layer made of a semiconductor material has a band gap energy in a range of Eg=1.6 to 1.9 eV, but can be others. The upper cell also has an upper n type window layer overlying the upper p type absorber layer, an upper transparent conductive oxide layer overlying the upper n type window layer, and an upper glass material overlying the upper transparent conductive oxide layer. Of course, there can be other variations, modifications, and alternatives.

Many benefits are achieved by ways of present invention. For example, the present invention uses starting materials that are commercially available to form a thin film of semiconductor bearing material overlying a suitable substrate member. The thin film of semiconductor bearing material can be further processed to form a semiconductor thin film material of desired characteristics, such as atomic stoichiometry, impurity concentration, carrier concentration, doping, and others. In a specific embodiment, the upper cell is configured to selectively filter certain wavelengths, while allowing others to pass and be processed in the lower cell. In a preferred embodiment, the upper cell configuration occurs using a preferred electrode layer, which can be combined or varied. In a preferred embodiment, the present configuration would replace the TCO, which is often an n+ type material, which is formed against a p type absorber leading to limitations, e.g., second junction. In a preferred embodiment, the present cell configuration and related method forms at least a p+ type buffer layer between the n+ type TCO from a lower cell and p type absorber from an upper cell. Again in a preferred embodiment, the present cell configuration and related method uses a p+ type transparent conductor that is not completely transparent across a range of wavelengths of sunlight but selectively allows passage of wavelengths in the red light range, which can be used in the lower cell. In a preferred embodiment, the p+ type transparent conductor material is characterized by about the same bandgap as the absorber layer and improves efficiency of the upper cell. Additionally, the present method uses environmentally friendly materials that are relatively less toxic than other thin-film photovoltaic materials. Depending on the embodiment, one or more of the benefits can be achieved. These and other benefits will be described in more detailed throughout the present specification and particularly below.

Merely by way of example, the present method and materials include absorber materials made of copper indium disulfide species, copper tin sulfide, iron disulfide, or others for single junction cells or multi-junction cells. Other materials can also be used according to a specific embodiment.

### BRIEF DESCRIPTION OF THE DRAWINGS

FIG. 1 is a simplified diagram of four terminal multi-junction photovoltaic cell according to an embodiment of the present invention;

FIG. 2 is a simplified diagram of a cross-sectional view diagram of a multi-junction photovoltaic cell according to an embodiment of the present invention; and

FIG. 3 is a simplified diagram illustrating a selective filtering process according to a specific embodiment of the present invention.

### DETAILED DESCRIPTION OF THE INVENTION

According to embodiments of the present invention, a method and a structure for forming thin film semiconductor materials for photovoltaic applications are provided. More particularly, the present invention provides a method and structure for manufacture of high efficiency multi-junction thin film photovoltaic cells. Merely by way of example, the present method and materials include absorber materials made of copper indium disulfide species, copper tin sulfide, iron disulfide, or others for multi-junction cells.

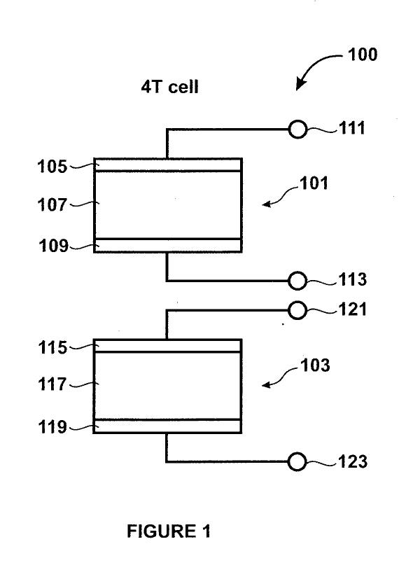

FIG. 1 is a simplified diagram 100 of a four terminal multi-junction photovoltaic cell according to an embodiment of the present invention. The diagram is merely an illustration and should not unduly limit the scope of the claims herein. One of ordinary skill in the art would recognize other variations, modifications, and alternatives. As shown, the present invention provides a multi-junction photovoltaic cell device 100. The device includes a lower cell 103 and an upper cell 101, which is operably coupled to the lower cell. In a specific embodiment, the term lower and upper are not intended to be limiting but should be construed by plain meaning by one of ordinary skill in the art. In general, the upper cell is closer to a source of electromagnetic radiation, than the lower cell, which receives the electromagnetic radiation after traversing through the upper cell. Of course, there can be other variations, modifications, and alternatives.

In a specific embodiment, the lower cell includes a lower glass substrate material 119, e.g., transparent glass, soda lime glass, or other optically transparent substrate or other substrate, which may not be transparent. The lower cell also includes a lower electrode layer made of a reflective material overlying the glass material. The lower cell includes a lower absorber layer overlying the lower electrode layer. As shown, the absorber and electrode layer are illustrated by reference numeral 117. In a specific embodiment, the absorber layer is made of a semiconductor material having a band gap energy in a range of Eg=0.7 to 1 eV, but can be others. In a specific embodiment, the lower cell includes a lower window layer overlying the lower absorber layer and a lower transparent conductive oxide layer 115 overlying the lower window layer.

In a specific embodiment, the upper cell includes a p+ type transparent conductor layer 109 overlying the lower transparent conductive oxide layer. In a preferred embodiment, the p+ type transparent conductor layer is characterized by traversing electromagnetic radiation in at least a wavelength range from about 700 to about 630 nanometers and filtering electromagnetic radiation in a wavelength range from about 490 to about 450 nanometers. In a specific embodiment, the upper cell has an upper p type absorber layer overlying the p+ type transparent conductor layer. In a preferred embodiment, the p type conductor layer made of a semiconductor material has a band gap energy in a range of Eg=1.6 to 1.9 eV, but can be others. The upper cell also has an upper n type window layer overlying the upper p type absorber layer. Referring again to FIG. 1, the window and absorber are illustrated by reference numeral 107. The upper cell also has an upper transparent conductive oxide layer 105 overlying the upper n type window layer and an upper glass material overlying the upper transparent conductive oxide layer. Of course, there can be other variations, modifications, and alternatives.

In a specific embodiment, the multi-junction photovoltaic cell includes four terminals. The four terminals are defined by reference numerals 111, 113, 121, and 123. Alternatively, the multi-junction photovoltaic cell can also include three terminals, which share a common electrode preferably proximate to an interface region between the upper cell and the lower cell. In other embodiments, the multi-junction cell can also include two terminals, among others, depending upon the application. Examples of other cell configurations are provided in U.S. Provisional Patent Application No. 60/988,414, filed Nov. 11, 2007, commonly assigned and hereby incorporated by reference herein. Of course, there can be other variations, modifications, and alternatives. Further details of the four terminal cell can be found throughout the present specification and more particularly below.

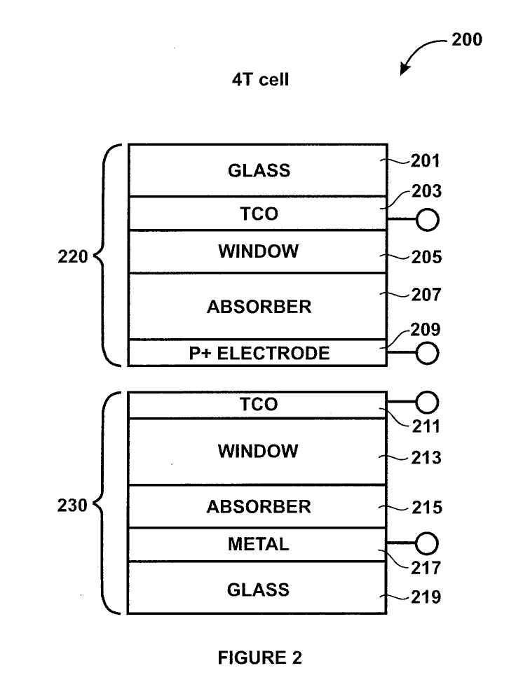

FIG. 2 is a simplified diagram of a cross-sectional view diagram 200 of a multi-junction photovoltaic cell according to an embodiment of the present invention. The diagram is merely an illustration and should not unduly limit the scope of the claims herein. One of ordinary skill in the art would recognize other variations, modifications, and alternatives. As shown, the present invention provides a multi-junction photovoltaic cell device 200. The device includes a lower cell 230 and an upper cell 220, which is operably coupled to the lower cell. In a specific embodiment, the term lower and upper are not intended to be limiting but should be construed by plain meaning by one of ordinary skill in the art. In general, the upper cell is closer to a source of electromagnetic radiation, than the lower cell, which receives the electromagnetic radiation after traversing through the upper cell. Of course, there can be other variations, modifications, and alternatives.

In a specific embodiment, the lower cell includes a lower glass substrate material 219, e.g., transparent glass, soda lime glass, or other optically transparent substrate or other substrate, which may not be transparent. The glass material or substrate can also be replaced by other materials such as a polymer material, a metal material, or a semiconductor material, or any combinations of them. Additionally, the substrate can be rigid, flexible, or any shape and/or form depending upon the embodiment. Of course, there can be other variations, modifications, and alternatives.

In a specific embodiment, the lower cell also includes a lower electrode layer 217 made of a reflective material overlying the glass material. The reflective material can be a single homogeneous material, composite, or layered structure according to a specific embodiment. In a specific embodiment, the lower electrode layer is made of a material selected from aluminum, silver, gold, molybdenum, copper, other metals, and/or conductive dielectric film(s), and others. The lower reflective layer reflects electromagnetic radiation that traversed through the one or more cells back to the one or more cells for producing current via the one or more cells. Of course, there can be other variations, modifications, and alternatives.

As shown, the lower cell includes a lower absorber layer 215 overlying the lower electrode layer. In a specific embodiment, the absorber layer is made of a semiconductor material having a band gap energy in a range of Eg=0.7 to 1 eV, but can be others. In a specific embodiment, the lower absorber layer is made of the semiconductor material selected from Cu₂SnS₃, FeS₂, and CuInSe₂. The lower absorber layer comprises a thickness ranging from about a first determined amount to a second determined amount, but can be others. Depending upon the embodiment, the lower cell can be formed using a copper indium gallium selenide (CIGS), which is copper, indium, gallium, and selenium. Of course, there can be other variations, modifications, and alternatives.

In a specific embodiment, the material includes copper indium selenide (“CIS”) and copper gallium selenide, with a chemical formula of CuInₓGa₍₁₋ₓ₎Se₂, where the value of x can vary from 1 (pure copper indium selenide) to 0 (pure copper gallium selenide). In a specific embodiment, the CIGS material is characterized by a bandgap varying with x from about 1.0 eV to about 1.7 eV, but may be others, although the band gap energy is preferably between about 0.7 to about 1.1 eV. In a specific embodiment, the CIGS structures can include those described in U.S. Pat. Nos. 4,611,091 and 4,612,411, which are hereby incorporated by reference herein, as well as other structures. Of course, there can be other variations, modifications, and alternatives.

In a specific embodiment, the lower cell includes a lower window layer overlying the lower absorber layer and a lower transparent conductive oxide layer 215 overlying the lower window layer. In a specific embodiment, the lower window layer is made of material selected from cadmium sulfide, cadmium zinc sulfide, or other suitable materials. In other embodiments, other n-type compound semiconductor layer include, but are not limited to, n-type group II-VI compound semiconductors such as zinc selenide, cadmium selenide, but can be others. Of course, there can be other variations, modifications, and alternatives. The transparent conductor oxide layer is indium tin oxide or other suitable materials.

In a specific embodiment, the upper cell includes a p+ type transparent conductor layer 209 overlying the lower transparent conductive oxide layer. In a preferred embodiment, the p+ type transparent conductor layer is characterized by traversing electromagnetic radiation in at least a wavelength range from about 700 to about 630 nanometers and filtering electromagnetic radiation in a wavelength range from about 490 to about 450 nanometers. In a preferred embodiment, the p+ type transparent conductor layer comprises a ZnTe species, including ZnTe crystalline material or polycrystalline material. In one or more embodiments, the p+ type transparent conductor layer is doped with at least one or more species selected from Cu, Cr, Mg, O, Al, or N, combinations, among others. In a preferred embodiment, the p+ type transparent conductor layer is characterized to selectively allow passage of red light and filter out blue light having a wavelength ranging from about 400 nanometers to about 450 nanometers. Also in a preferred embodiment, the p+ type transparent conductor layer is characterized by a band gap energy in a range of Eg=1.6 to 1.9 eV, or a band gap similar to the upper p type absorber layer. Of course, there can be other variations, modifications, and alternatives.

In a specific embodiment, the upper cell has an upper p type absorber layer 207 overlying the p+ type transparent conductor layer. In a preferred embodiment, the p type conductor layer made of a semiconductor material has a band gap energy in a range of Eg=1.6 to 1.9 eV, but can be others. In a specific embodiment, the upper p type absorber layer is selected from CuInS₂, Cu(In,Al)S₂, Cu(In,Ga)S₂, or other suitable materials. The absorber layer is made using suitable techniques, such as those described in U.S. Ser. No. 61/059,253 filed Jun. 5, 2008, commonly assigned, and hereby incorporated by reference here.

Referring back to FIG. 2, the upper cell also has an upper n type window layer 205 overlying the upper p type absorber layer. In a specific embodiment, the n type window layer is selected from a cadmium sulfide (CdS), a zinc sulfide (ZnS), zinc selenium (ZnSe), zinc oxide (ZnO), zinc magnesium oxide (ZnMgO), or others and may be doped with impurities for conductivity, e.g., n⁺ type. The upper cell also has an upper transparent conductive oxide layer 203 overlying the upper n type window layer according to a specific embodiment. The transparent oxide can be indium tin oxide and other suitable materials. For example, TCO can be selected from a group consisting of In₂O₃:Sn (ITO), ZnO:Al (AZO), SnO₂:F (TFO), and can be others.

In a specific embodiment, the upper cell also includes a cover glass 201 or upper glass material overlying the upper transparent conductive oxide layer. The upper glass material provides suitable support for mechanical impact and rigidity. The upper glass can be transparent glass or others. Of course, there can be other variations, modifications, and alternatives.

In a specific embodiment, the multi-junction photovoltaic cell includes upper cell 220, which is coupled to lower cell 230, in a four terminal configuration. Alternatively as noted, the multi-junction photovoltaic cell can also include three terminals, which share a common electrode preferably proximate to an interface region between the upper cell and the lower cell. In other embodiments, the multi-junction cell can also include two terminals, among others, depending upon the application. Of course, there can be other variations, modifications, and alternatives. Further details of the four terminal cell can be found throughout the present specification and more particularly below.

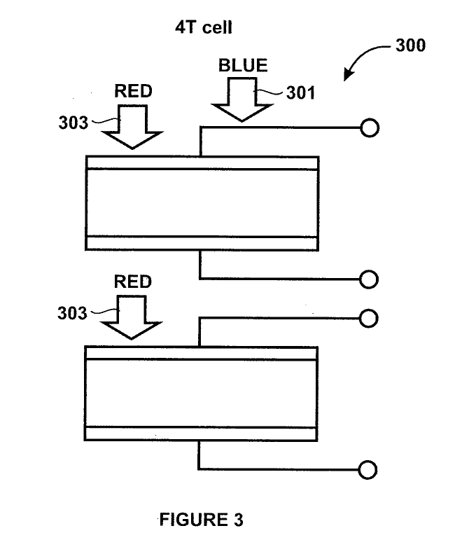

FIG. 3 is a simplified diagram illustrating a selective filtering process according to a specific embodiment of the present invention. The diagram is merely an illustration and should not unduly limit the scope of the claims herein. One of ordinary skill in the art would recognize other variations, modifications, and alternatives. As shown is a method for using a multi-junction photovoltaic cell, such as those described in the present specification. In a specific embodiment, the method includes irradiating sunlight through an upper cell operably coupled to a lower cell. As shown, the irradiation generally includes wavelengths corresponding to blue light 301 and red light 303, including slight or other variations. In a specific embodiment, the upper cell comprising a p+ type transparent conductor layer overlying a lower transparent conductive oxide layer. The p+ type conductor layer is also coupled to a p-type absorber layer and also has a substantially similar band gap as the absorber layer to effectively lengthen the absorber layer. As shown, the method selectively allows for traversing the electromagnetic radiation from the sunlight in at least a wavelength range from about 700 to about 630 nanometers through the p+ type transparent conductor layer. In a preferred embodiment, the p+ type conductor layer also filters out or blocks electromagnetic radiation in a wavelength range from about 490 to about 450 nanometers through the p+ type transparent conductor layer. Depending upon the embodiment, the method also includes other variations. In a specific embodiment, the colors of the visible light spectrum color wavelength interval frequency interval are listed below.

red˜700-630 nm˜430-480 THz
orange˜630-590 nm˜480-510 THz
yellow˜590-560 nm˜510-540 THz
green˜560-490 nm˜540-610 THz
blue˜490-450 nm˜610-670 THz
violet˜450-400 nm˜670-750 THz

In a preferred embodiment, the present multi-junction cell has improved efficiencies. As an example, the present multi-junction cell has an upper cell made of CuInS₂ that has an efficiency of about 12.5% and greater or 10% and greater according to a specific embodiment. The efficiency is commonly called a “power efficiency” measured by electrical power out/optical power in. Of course, there may also be other variations, modifications, and alternatives.

Although the above has been illustrated according to specific embodiments, there can be other modifications, alternatives, and variations. It is understood that the examples and embodiments described herein are for illustrative purposes only and that various modifications or changes in light thereof will be suggested to persons skilled in the art and are to be included within the spirit and purview of this application and scope of the appended claims.

What is claimed is:

1. A multi-junction photovoltaic cell device comprising:
a lower cell comprising:
a lower glass substrate material;
a lower electrode layer made of a reflective material overlying the glass material;
a lower absorber layer overlying the lower electrode layer, the absorber layer made of a semiconductor material having a band gap energy in a range of Eg=0.7 to 1 eV;
a lower window layer overlying the lower absorber layer;
a lower transparent conductive oxide layer overlying the lower window layer;
an upper cell operably coupled to the lower cell, the upper cell comprising:
a p+ type transparent conductor layer overlying the lower transparent conductive oxide layer, the p+ type transparent conductor layer characterized by traversing electromagnetic radiation in at least a wavelength range from about 700 to about 630 nanometers and filtering electromagnetic radiation in a wavelength range from about 490 to about 450 nanometers;
an upper p type absorber layer overlying the p+ type transparent conductor layer, the p type conductor layer made of a semiconductor material having a band gap energy in a range of Eg=1.6 to 1.9 eV;
an upper n type window layer overlying the upper p type absorber layer;
an upper transparent conductive oxide layer overlying the upper n type window layer; and
an upper glass material overlying the upper transparent conductive oxide layer.

2. The device of claim 1 wherein the lower absorber layer is made of the semiconductor material selected from Cu₂SnS₃, FeS₂, or CuInSe₂.

3. The device of claim 1 wherein the lower absorber layer comprises a thickness ranging from about first predetermined amount to a second predetermined amount.

4. The device of claim 1 wherein the lower electrode layer, the lower transparent conductor layer, the p+ type transparent conductor layer, and the upper transparent conductive oxide layer are respectively first electrode, second electrode, third electrode, and fourth electrode.

5. The device of claim 1 wherein the bottom cell is configured to absorb electromagnetic radiation in a red wavelength range.

6. The device of claim 1 wherein the lower glass substrate material is selected from optical glass.

7. The device of claim 1 wherein the lower electrode layer is made of a material selected from aluminum, silver, gold, or molybdenum.

8. The device of claim 1 wherein the lower window layer is made of material selected from an n-type material.

9. The device of claim 1 wherein the lower transparent conductive oxide layer is selected from a transparent indium oxide.

10. The device of claim 1 wherein the p+ type transparent conductor layer is selected from a zinc bearing species.

11. The device of claim 1 wherein the p+ type transparent conductor layer comprises a ZnTe species.

12. The device of claim 11 wherein the p+ type transparent conductor layer is doped with at least one or more species selected from Cu, Cr, Mg, O, Al, or N.

13. The device of claim 12 wherein the p+ type transparent conductor layer is characterized to selectively allow passage of red light and filter out blue light having a wavelength ranging from about 400 nanometers to about 450 nanometers.

14. The device of claim 1 wherein the p+ type transparent conductor layer is characterized by a band gap energy in a range of Eg=1.6 to 1.9 eV.

15. The device of claim 1 wherein the upper p type absorber layer is selected from CuInS₂, Cu(In,Al)S₂, or Cu(In,Ga)S₂.

16. The device of claim 1 wherein the upper n type window layer is selected from a cadmium sulfide (CdS), a zinc sulfide (ZnS), zinc selenium (ZnSe), zinc oxide (ZnO), or zinc magnesium oxide (ZnMgO).

17. The device of claim 1 wherein the upper transparent conductive oxide layer is selected from In₂O₃:Sn (ITO), ZnO:Al (AZO), or SnO₂:F (TFO).

18. The device of claim 1 wherein the upper glass material is selected from transparent glass.

19. A method for using a multi-junction photovoltaic cell, the method comprising:
irradiating sunlight through an upper cell operably coupled to a lower cell, the upper cell comprising a p+ type transparent conductor layer overlying a lower transparent conductive oxide layer;
selectively traversing electromagnetic radiation from the sunlight in at least a wavelength range from about 700 to about 630 nanometers and filtering electromagnetic radiation in a wavelength range from about 490 to about 450 nanometers through the p+ type transparent conductor layer.
